(19) United States
(12) Patent Application Publication
(10) Pub. No.: US 2003/0211747 A1
(43) Pub. Date: Nov. 13, 2003

(54) Shallow trench isolation polishing using mixed abrasive slurries

(75) Inventors: Sharath Hegde, Potsdam, NY (US); Anurag Jindal, Potsdam, NY (US); Suryadevara V. Babu, Potsdam, NY (US)

Correspondence Address: Alvin Isaacs, Esq., 9544 Hawksmoor Lane, Sarasota, FL, 34238-3221, US

(73) Assignee: NYACOL NANO TECHNOLOGIES, INC

(21) Appl. No.: 10/449,891

(22) Filed: Jun. 2, 2003

Related U.S. Application Data
(63) Continuation-in-part of application No. 10/095,777, filed on Mar. 13, 2002.
Application No. 10/095,777 is a continuation-in-part of application No. 09/950,612, filed on Sep. 13, 2001.

(51) Int. Cl. H01L 21/311

(52) U.S. Cl. 438/700

(57) ABSTRACT

Isolation of active areas, e.g., transistors, in integrated circuits and the like so that functioning of one active area does not interfere with neighboring ones, is provided by the shallow trench isolation technique followed by chemical-mechanical polishing with a mixed abrasive slurry consisting essentially of (a) relatively large, hard inorganic metal oxide particles having (b) relatively small, soft inorganic metal oxide particles adsorbed on the surface thereof so as to modify the effective charge of the slurry to provide more favorable selectivity of silicon dioxide to silicon nitride, the slurry having a pH below about 5.

### RELATED APPLICATION

This application is a continuation-in-part of our copending application, Ser. No. 10/095,777 , which in turn is a continuation-in-part of Ser. No. 09/950,612 filed Sep. 13, 2001.

### BACKGROUND OF THE INVENTION

For integrated circuits to function properly, each of the millions of active areas, e.g., transistors, should be isolated so that functioning of one transistor does not interfere with the neighboring ones.

The most common method of isolating the active areas in complimentary metal oxide semiconductor circuits, until 0.5 micron device sealing, was local oxidation of silicon. A buffer layer of silicon dioxide (SiO₂) was first deposited over the silicon substrate. A silicon nitride (Si₃N₄) layer was then deposited on the silicon dioxide layer. The silicon dioxide layer acts as a sacrificial layer to prevent cracking of the nitride film due to different coefficients of thermal expansion and is accordingly deposited first on the silicon substrate surface.

The silicon nitride layer is then patterned to expose the area(s) where isolation is required.

Next, the silicon substrate is thermally oxidized, by either the per se known wet or dry process, to provide a thick, e.g. 0.5 to 1.0 micrometer, pattern of silicon dioxide in those regions where there is no nitride. Because the oxidizing reagent, oxygen or steam, does not diffuse through the nitride layer, the nitride functions as a mask against the oxidation. After the nitride is removed using acids at highly elevated temperatures, the thick oxide grown in those regions where the nitride was not present serves to electrically isolate the transistors or other active areas from neighboring ones.

The technique of local oxidation of silicon, as mentioned above, provides isolation which introduces non-polarity and a “bird's beak” at the edge of the active region, as illustrated in FIG. 1, to be discussed hereinafter. Consequently, the packing density, i.e. the number of active devices, e.g. transistors, per unit area of silicon substrate, is markedly reduced. This, in turn, makes the local oxidation of silicon technique undesirable at sub-quarter micron dimensions.

As a result, new isolation schemes have been introduced in advanced sub-quarter micron processes.

One such process is called shallow trench isolation. In the current generation devices, an improved isolation, greater packing density and superior dimension control is sought after by using the shallow trench isolation method.

After etching trenches into the nitride and silicon substrate, oxide is deposited either by chemical vapor deposition or the “spin on glass” technique. The last step, involving the oxide “overburden removal” is accomplished by chemical-mechanical polishing (“CMP”).

CMP is per se well known and has in fact emerged as the only technique to planarize metal and dielectric films for the fabrication of microelectric devices on the integrated circuits.

The process of manufacturing integrated circuits typically consists of more than a hundred steps during which a large number of integrated circuits are formed on a single silicon wafer. The challenges involved in the chip manufacturing make the integrated circuit industry one of the most demanding industries in recent time.

Aluminum and silicon dioxide have been conventionally employed for fabricating the interconnects during chip manufacture. Aluminum is used as a conductor to connect different devices; and silicon dioxide is used as an insulating material between the conductors and between the devices.

Silicon dioxide and silicon nitride polishing are crucial because of the Shallow Trench Isolation procedure for the isolation of adjacent active devices. As alluded to above, each of the many million transistors must be properly isolated so that the functioning of one transistor does not interfere with that of an adjacent one.

In the current generation devices, an improved isolation, greater packing density and superior dimensional control is achieved by the aforementioned Shallow Trench Isolation method. Notably, Shallow Trench Isolation is formed by etching a trench through the silicon nitride and the silicon oxide layers into the silicon substrate to a predetermined depth. Silicon oxide is then deposited over the entire wafer and into the trench opening in the silicon nitride using a special technique known in the art as Chemical Vapor Deposition (“CVD”). Chemical-mechanical polishing is then applied to remove excess CVD silicon oxide and is stopped on the protective silicon nitride. The nitride is then etched out using strong, hot acids.

CMP must stop when the nitride layer is reached and this requires a very high oxide-to-nitride-selectivity-slurry for CMP. In the CMP process, as the name of the process infers, planarization is achieved through the contributions of both chemical reactions and mechanical abrasion. The chemical reactions take place between the slurry and the material being polished. Mechanical abrasion of the film is caused by the interaction between the pad, the abrasives and the film.

Accordingly, the three major components of a CMP process are the film, the pad and the slurry. Since the process is very well known in the art, including its essential components, it need not be discussed in much detail herein.

Of these three major components, it is stressed that the use of highly selective slurries which yield minimal defects in the shallow trench isolation procedure is by far the most critical for providing a commercial product. Accordingly, it is stressed that providing highly selective slurries which yield minimal defects after chemical -mechanical polishing of the shallow trench isolation is essential for a vitally important and commercial shallow trench isolation system.

It is to this task to which the present invention is directed.

### BRIEF DESCRIPTION OF THE INVENTION

In accordance with the present invention, this task is solved in an elegant, cost-effective manner by providing a mixed abrasive polishing slurry for the CMP process consisting essentially of at least two inorganic metal oxide abrasive materials such as ceria (CeO₂) and alumina (Al₂O₃) particles at a pH below 5, e.g. on the order of ˜4.0 or less in order to control the polish rate selectivity of oxide to nitride and to reduce surface defects.

The mixed abrasive slurries (“MAS”) will consist essentially of a mixture of (a) small and soft particles and (b) relatively large and hard particles as will be described in detail hereinafter. The two kinds of slurry particles are selected to provide opposite polarity such that the smaller particles are attracted to and thereby preferentially adsorbed on the surface of the larger particles.

A critical advantage of this preferential adsorption of the small particles on the large particles in the slurry is that it modifies the effective charge of the slurry such that the interaction between silicon dioxide and the modified abrasive is favorable while that between silicon nitride and the modified abrasive is not favorable, thus providing desired high oxide to nitride selectivity.

Further, while the large, hard particles provide the necessary mechanical abrasion function of the slurries, the small, soft particles present on the surface of the large particles lead to improved surface roughness.

In essence, the mixed abrasive slurry of this invention provides a synergistic interplay at the recited pH<5.0 between the soft and hard particles in the slurry, which interplay is the key to obtaining optimally high and selective removal of oxide over nitride by chemical mechanical polishing in accordance with the practice of this invention.

### DESCRIPTION OF THE DRAWINGS

FIG. 1 is a schematic view of the prior art local oxidation of silicon, illustrating the “bird's beak” at the edge of the active region;

FIG. 2 is a schematic view of the Shallow Trench Isolation technique to which the present invention is directed

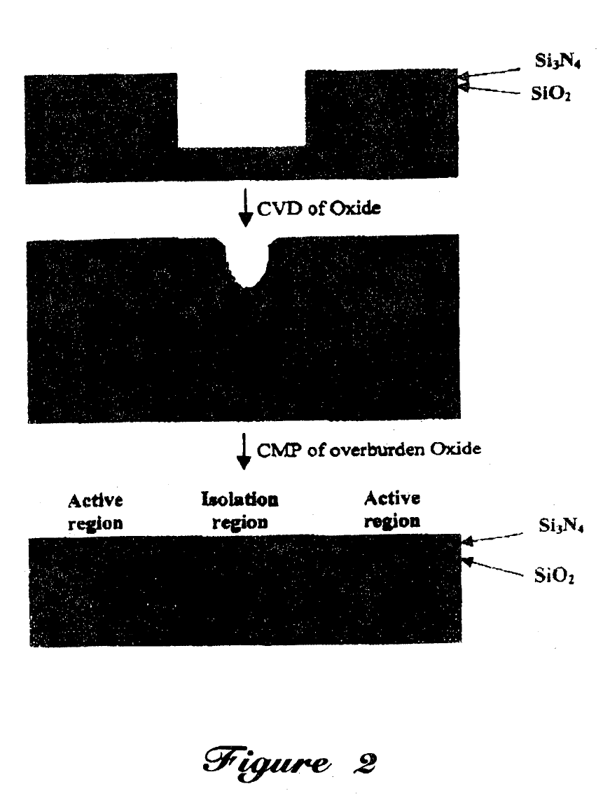

FIG. 3(a) is a Transmission electron microscope image of a single dried alumina particle in a slurry;

FIG. 3(b) is a view similar to FIG. 3(a) of a dried mixed abrasive particle after centrifuging from an abrasive slurry containing colloidal ceria and calcined alumina and;

FIG. 4 is a schematic view of a polishing mechanism by abrasives in a mixed abrasive slurry in accordance with this invention

### DETAILED DESCRIPTION OF THE INVENTION

As was alluded to above, for integrated circuit devices and the like to function properly, each of the many million transistors in a chip should be properly isolated so that functioning of one transistor does not interfere with that of an adjacent transistor. As the state of the art of isolation of transistors from neighboring ones evolved, the current generation techniques utilize shallow trench isolation, as previously described in the BACKGROUND OF THE INVENTION.

The present invention is directed to improvements in these Shallow Trench Isolation procedures utilizing novel mixed abrasive slurries at a critical pH less than 5 to control the polish rate selectivity of the oxide to nitride in the CMP polishing step with the slurry in order to control the polish rate selectivity of oxide to nitride and to reduce surface defects.

The invention will be readily understood by reference to the following detailed description taken in conjunction with the accompanying drawings.

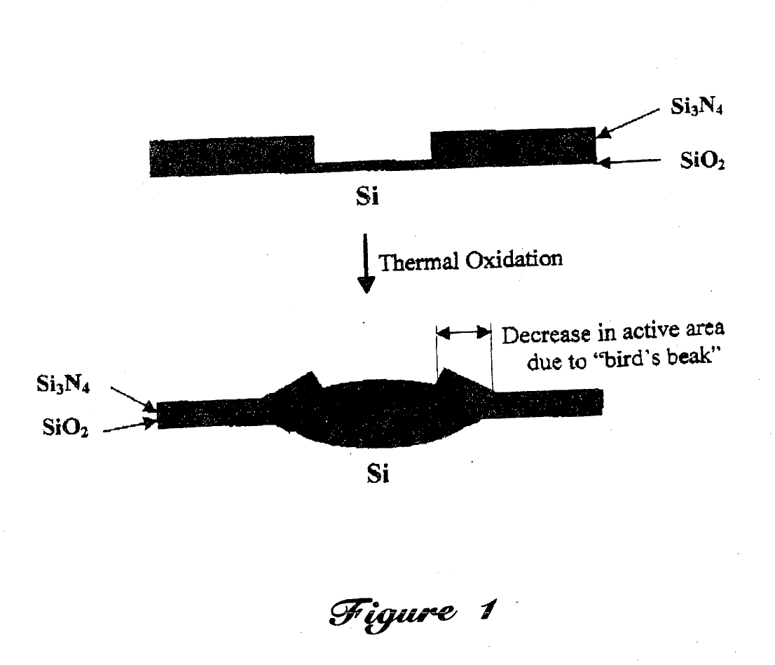

Shallow Trench Isolation exhibits a high degree of planarity and a remarkable reduction in the chip area required for isolation due to the elimination of the “bird's beak” previously mentioned and illustrated in FIG. 1. Therefore, oxide CMP should ensure that the defects (scratches, pits and particle adhesion) are minimized. Moreover, CMP should stop at the nitride stop layer. Further, because the oxide CMP processes tend to have a low polish rate selectivity, i.e. ratio of polish rate of oxide to that of nitride, the amount of over-polishing should be minimal.

It is for this reason that Applicants have stressed that the use of highly selective slurries which yield minimal defects after CMP is essential for a vitally important and commercial shallow trench isolation system.

By way of review, a typical slurry for use in chemical-mechanical polishing consists of a solid phase of abrasive material and a liquid chemical solution phase. The abrasives in the slurry play the very important role of transferring mechanical energy to the surface being polished. Illustrative abrasives which have been used for this purpose include silica (silicon dioxide, SiO₂) and alumina (aluminum oxide, Al₂O₃) . Ceria (cerium dioxide, CeO₂) is the most popular abrasive for the polishing of glass and (recently) oxide films for Shallow Trench Isolation.

Conventionally, silica particles alone were used as the abrasive for silicon oxide and nitride polishing. Ceria-based slurries, which have high removal rates of oxide and nitride and high selectivity of oxide to nitride often cause slurry-induced scratches on the oxide surface, These scratches are detrimental to proper functioning of the integrated circuit devices. Deep scratches especially should be eliminated because they may attack the silicon substrate and negate oxide integrity.

The “grandparent” application to this invention, the aforementioned application Ser. No. 09/950,612, describes and claims abrasive slurries consisting essentially of two or more of the per se known inorganic metal oxide abrasives in order to obtain improved polish rates, controlled polish rate selectivity, low surface defectivity and slurry stability, a mixture of either alumina and silica or alumina and ceria being preferred.

The mixed abrasive slurries of the parent case are stated to constitute an unexpected technological advancement in CMP processes. Specifically, it has been unexpectedly observed that the mixed abrasive slurry provides superior performance to slurries of either abrasive alone, as confirmed by performance data in that application.

As was stated in the parent application, the patent literature is replete with references to chemical-mechanical polishing processes reciting the use of a slurry including an inorganic metal oxide abrasive material selected from the group consisting of alumina, titania, zirconia, germania, silica, ceria and mixtures thereof. As examples of such patents, mention may be made of U.S. Pat. Nos. 5,759,917 issued to Grover et al.; 5,958,288 issued to Mueller et al.; 5,980,775 issued to Grumbine et al.; 6,068,787 issued to Grumbine et al. ; and U.S. Patent Application Publications Nos. US 2001/0006225 A1 issued to Tsuchiya et al. and 2001/0008828 Al issued to Uchikura et al., all of which are cited in the INFORMATION DISCLOSURE STATEMENT filed in the parent case and therefore incorporated by reference herein.

However, Applicants stress that to the best of their knowledge and recollection, in no instance was there a specific example reciting a slurry containing only a combination of two or more of the above inorganic metal oxide abrasives, much less the specified combination of inorganic metal oxide abrasives alluded to in the BRIEF DESCRIPTION OF THE INVENTION and described in greater particularity hereinafter. Instead, in all instances reciting the above-mentioned known class of inorganic metal oxide abrasives, patentable novelty was predicated upon other reagents in the slurry, e.g., at least one of the following specific reagents: a carboxylic acid; a salt; a soluble metal; a catalyst, an oxidizing agent; a stabilizer; a pH buffering agent; a chelating agent; an adhesion-inhibitor; a polishing rate adjuster, etc.

In this context, attention is respectfully invited to the aforementioned U.S. Pat. No. 5,759,917 of Grover et al. (“Grover”) relied upon by the Examiner in the parent application, Ser. No. 09,950,612. Grover claims a chemical mechanical polishing composition comprising carboxylic acid, a salt and a soluble cerium compound at a pH above three that can selectively polish a silicon oxide overfill in preference to a silicon nitride film layer in a single step. Grover mentions that this chemical composition can be used either in conjunction with the abrasive or alone to achieve the desired selectivity.

Notably, however, it was evident from the examples cited in the patent that when the abrasive slurry was used alone without any additives, the selectivity of oxide to nitride was very poor (<5). This was seen for both pulverized ceria and precipitated ceria slurries (Examples 2 and 3) . Even at high concentrations of the precipitated ceria (20%) the removal rtes of oxide and nitride were very low. It will thus be apparent that the chemical concentration containing carboxylic acid, salt and soluble cerium compound used in the Grover patented invention was critical in bringing in the high selectivity of oxide over nitride. From these examples and from Applicants own experiments, it is clear that abrasive particles alone (as taught by the prior art) do not offer selective polishing of oxide.

As distinguished therefrom, the present invention is directed to a slurry for CMP polishing procedures having a pH below ˜5 and consisting essentially of (a) large, hard particles having (b) small, soft particles adsorbed on the surface of the larger particles so as to modify the effective charge of the slurry such that the interaction between silicon dioxide and the thus modified abrasive is favorable ; while that between the silicon nitride and the modified abrasive is not so favorable, thus providing the desired high oxide to nitride selectivity needed to accomplish the task of the invention.

The large, hard particles in the slurry, which provide the necessary mechanical abrasion function of the slurry, will, for example, possess a mean particle size of on the order of from about 80 to 250 nm ; while the small, soft particles adsorbed on the surface of the large particles may, for instance, be on the order of from about 10-40 nm. The ratio of large to small particles may, for instance, be on the order of from about 1:1 to about 1:5 by weight, preferably from 1:1 to 1:1.2 by weight.

The large, hard particles will preferably have a rating of 7-9 on the mohs hardness scale; while the small, soft particles will preferably have a rating of about 2-3 on the mohs hardness scale.

As examples of useful large particles, mention may be made of alumina, iron oxide, chromia, ceria, titania, germania and zirconia; while examples of useful materials for the small particles include silica, zirconia and ceria.

The adsorption of the small particles onto the surface of the large particles is provided by the attractive force of the opposite polarity of the large and small particles.

Attention is now invited to the following analytical data relating to the present invention.

Six inch silicon wafers with thermal oxide and nitride films were polished using ceria (product code DP-6255, 19-135D and 95-001209, supplied by Nyacol Nano Technologies, Inc.) and alumina (calcined or colloidal) supplied by Ferro Corporation and Nyacol Nano Technologies, Inc., respectively. Table I lists some of the specifications for these particles as well as their suppliers.

TABLE I
Slurry Particles and their Suppliers

| No. | Particle | Supplier | Remarks |
|---|---|---|---|
| 1 | Colloidal Cena at pH 9 | Nyacol | Size: ˜15 nm; acetates and |
| | (DP-6255) | | nitrates as counter ions |
| 2 | Colloidal Ceria at pH 1.5 | Nyacol | Size: ˜35 nm; acetates and |
| | (19-135D) | | nitrates as counter ions |
| 3 | Colloidal Ceria at pH 1.5 | Nyacol | Size: ˜15 nm; acetates and |
| | (95-001209) | | nitrates as counter ions |
| 4 | Colloidal Alumina at pH 4 | Nyacol | Size: ˜100 nm |
| | (AL-20) | | |
| 5 | Colloidal Alumina at pH 4 | Ferro | Size: ˜220 nm |
| | (3.5 g/cc bulk density) | | |

A Westech 372 polisher is used w/ the following parameters:

Pressure: 6.0 psi
Relative lin. I. ˜50 cm/s
Slurry flow rate: 200 ml
Pad: 1C-1400 ww/k groove
Polish Time: 2 minutes

With MAS containing colloidal ceria and alumina (colloidal/calcined), the polish rate of oxide is significantly improved while that of nitride is kept to a minimum. The polish rate selectivity in this case is >30 in all cases with surface roughness (root mean square, R_{q}) less than 1 nm. The surface quality after polishing is the best when colloidal alumina (AL-20) is used in the -mixed abrasive slurry. It has also been indicated that oxide polish rates can be independently controlled by using alumina of different kinds without much compromise on the surface roughness.

Nitride polish rate, on the other hand, is a very weak function of alumina particle type. This gives an independent control over the polish rate selectivity of oxide to nitride by using mixed abrasive slurries with colloidal ceria particles.

In all these experiments, thermally grown oxide (SiO₂) films have been used instead of chemical vapor deposited oxide. [It has been observed by many researchers that many chemical vapor deposition polish rates are higher than those of thermal oxide. This will further increase the polish rate selectivity of oxide to nitride.]

TABLE II
Polish Rates and Surface Roughness of Oxide and Nitride Films at pH < 5

| | | Oxide Film | | Nitride Film | | Polish Rate |
|---|---|---|---|---|---|---|
| | | Polish Rate | Roughness | Polish Rate | Roughness | Selectivity |
| No. | Slurry | (nm/min) | (nm) | (nm/min) | (nm) | (oxide/nitride) |
| 1 | 1.5% colloidal alumina | 8.0 | 0.7 | 0 | 0.9 | — |
| | (AL-20) at pH 4 | | | | | |
| 2 | 1.5% calcined alumina | 15.0 | 1.4 | 32.0 | — | — |
| | (Ferro) at pH 4 | | | | | |
| 3 | 3.0% colloidal ceria | 2.0 | — | 0 | — | — |
| | (19-135D) at pH 3.5 | | | | | |
| 4 | 3.0% colloidal ceria | 6.0 | 0.6 | 2.0 | — | 3.0 |
| | (95-001209) at pH 3.5 | | | | | |
| 5 | 1.5% alumina (AL-20) + | 65.0 | 0.7 | 2.0 | 0.8 | >32 |
| | 3.0% ceria (19135D) at | | | | | |
| | pH 3.5 | | | | | |
| 6 | 1.5% calcined alumina | 250.0 | 1.0 | 6.0 | 0.7 | >41 |
| | (Ferro) + 3.0% colloidal | | | | | |
| | ceria (19-135D) at pH 3.5 | | | | | |
| 7 | 1.5% calcined alumina | 132.0 | 0.7 | 2.0 | 0.7 | >65 |
| | (Ferro) + 3.0% colloidal | | | | | |
| | ceria (95-001209) at pH 3.5 | | | | | |

As seen, Table II shows the polish rates and surface roughness of oxide and nitride films using different slurries (containing either single or mixed abrasives at a pH<5.0, specifically at a pH from 3.0 to 4.0. In the experimentals of Table II, it was demonstrated either colloidal ceria or alumina alone does not polish both oxide and nitride. However, with a mixed abrasive slurry containing both colloidal ceria and alumina (colloidal/calcined), the polish rate of oxide is significantly improved, while that of nitride is kept at a minimum.

The polish rate selectivity with the mixed abrasive slurries was >30 in all instances with surface roughness ( root mean square, R_{q}) less than 1.0 nm. The surface quality after polishing is the best when colloidal alumina (AL-20) is used in the mixed abrasive slurry.

It has also been demonstrated that oxide polish rates can be independently controlled by using alumina of different kinds without much compromise on the surface roughness.

Nitride polish rate, on the other hand, is a very weak function of alumina particle type. This affords a further unexpected and unobvious advantage of the present invention, namely providing an independent control over the polish rate selectivity of oxide to nitride by employing mixed abrasive slurries with colloidal ceria particles.

Table III, hereinbelow, shows the iso-electric points of mixed abrasive slurries containing colloidal ceria and calcined alumina particles. Since mixed abrasive slurries in this study are employed at a pH far removed from the iso-electric points of the respective slurries, the slurry stability does not cause any concern.

TABLE III
Iso-Electric Points (IEP) of Mixed Abrasive Slurries
Containing Calcined Alumina & Colloidal Ceria

| No. | Slurry | IEP |
|---|---|---|
| 1 | 1.5% calcined alumina (Ferro) + | ˜5.6 |
| | 3.0% colloidal ceria (19-1350) | |
| 2 | 1.5% calcined alumina (Ferro) + | ˜6.1 |
| | 3.0% colloidal ceria (95-001209) | |

The following specific example of this invention will serve to further show by way of illustration and not by way of limitation the practice of the invention.

### EXAMPLE

TABLE
SiO₂ and Si₃N₄ removal rates with MAS-I and MAS-II Slurries

| | Si removal | Si₃N₄ | |
|---|---|---|---|
| Polishing | rate | removal | |
| Composition | (nm/min) | rate (nm/min | Selectivity |
| 3% colloidal ceria (DP-6225) | 10 | 8 | ˜1 |
| at pH 10 | | | |
| 1.5% calcined alumina at pH = 10 | 85 | 8 | 10 |
| 3% colloidal ceria (95-001209) | 6 | 2 | ˜3 |
| at pH = 4 | | | |
| 1.5% calcined alumina at pH = 4 | 15 | 32 | 0.5 |
| MAS-I: 3% colloidal ceria | 275 | 105 | 3 |
| (DP-6255) + 1.5% | | | |
| calcined alumina at pH 10 | | | |
| MAS-II 3% colloidal ceria | 132 | 2 | 66 |
| (95-001209) + 1.5% | | | |
| calcined alumina at pH = 4 | | | |

Iso-electric point (IEP) of a suspension containing colloidal particles is the value of pH at which the net surface charge on the particles is zero. The IEP of MAS-I containing colloidal ceria (DP-6255) from Nyacol Nano Technologies, Inc., mean particle size ˜15 nm) and calcined alumina (from Ferro Corporation, mean particle size ˜220 nm) in the ratio 2:1 to be ˜pH=2.1 and of MAS-II containing colloidal ceria (95-001209 from Nyacol Nano Technologies, Inc., mean particle size ˜nm) and calcined alumina (from Ferro Corporation) in the ratio 2:1 to be ˜pH=6.1 [1]. It is important, then, to note the charge behavior of the mixed abrasive particles in the colloidal suspension, of SiO₂ (silicon dioxide) and Si₃N₄ (Silicon Nitride), which are our polishing materials of choice under acidic and alkaline conditions. The IEP's of SiO₂ and Si₃N₄ are ˜pH=2 and 8, respectively. So, at pH=4, SiO₂ will have negative charge [2] and Si₃N₄ net positive charge [3] on the respective films. Since, at pH=4, MAS-II will have net positive charge and SiO₂ net negative charge, the interaction between the particles in MAS-II and he polishing substrate (SiO₂) is favorable and therefore we see high removal rate (RR) on SiO₂ (see above Table) at this pH. Si₃N₄, on the other hand, will have positive charge at this pH and the same sense of charge would exist on particles in MAS-II. This interaction between Si₃N₄ and particles in MAS-II is therefore not favorable and hence we see a low RR on Si₃N₄ at pH=4, leading to high selectivity of SiO₂ to Si₃N₄ RR at pH=4. At pH=10, SiO₂ will possess a strong negative charge and Si₃N₄ a weak negative charge. The mixed abrasive in the polish suspension (MAS-I) at this pH will also be strongly negative. Hence, the interaction of SiO₂ and mixed abrasive is not favorable while Si₃N₄-mixed abrasive interaction will be relatively much favored. The removal rate of SiO₂ at pH=10 is higher than at pH=4 due to its softer surface film in the alkaline pH regimes of polishing [4]. Hence, we see a reasonable removal rate on Si₃N₄ leading to poor selectivity between SiO₂ over Si₃N₄ RR at pH=10 compared to those at pH=4. It is further noted that the Moh's hardness value of ceria (DP-6255 and 95-001209) is ˜2-3, while that of calcined alumina is ˜8-9.

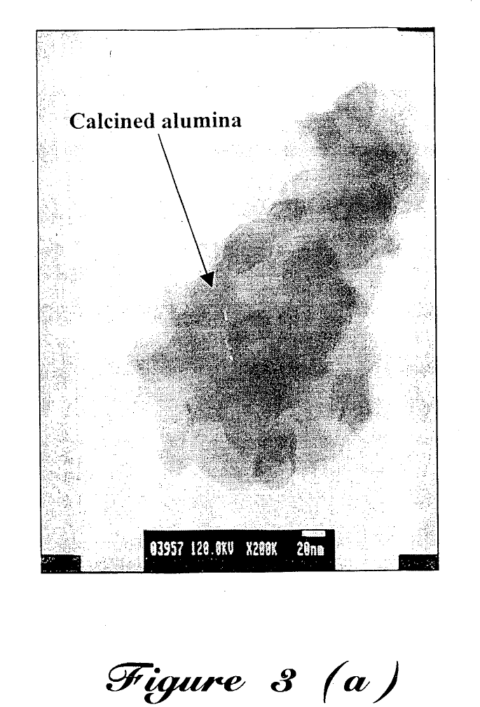

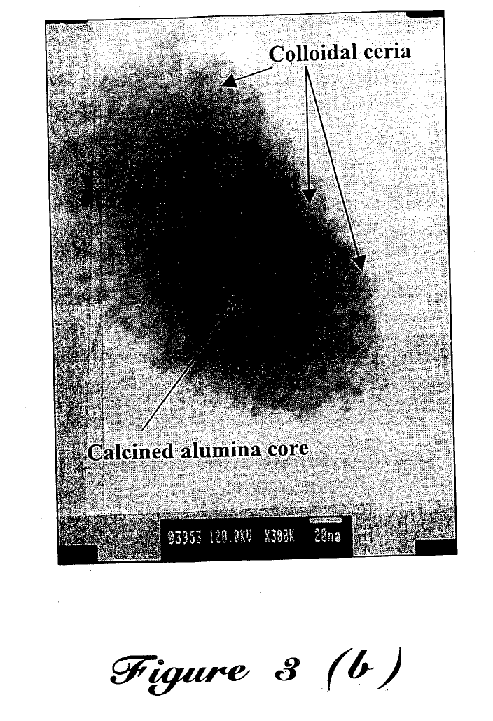

FIG. 3(a) is a transmission electron micrograph image depicting a single dried alumina particle in a slurry containing 3 wt % calcined alumina (Ferro Corp.) at pH=4 in which the sharp edges of the alumina are due to its crystallinity; while FIG. 3(b) is a similar image of a dried mixed abrasive particle after centrifuging and redispersing four times, the dried mixed abrasive particle being from a slurry containing 3wt % colloidal ceria (15 nm from Nyacol Nano Technology, Inc.), It will be observed in FIG. 3(b) the smaller, softer colloidal ceria particles are preferentially adsorbed on the larger, harder alumina particle, thereby forming a sheath around the alumina particles.

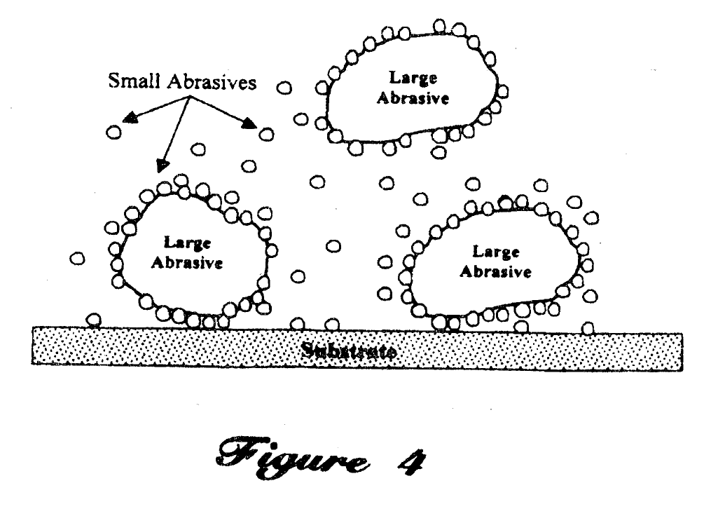

The schematic polishing mechanism of this invention illustrated in FIG. 4 shows how the small abrasive particles cluster around the surface of the large abrasive particles.

When the modified abrasive containing small, soft ceria particles adsorbed onto large, hard alumina particles interact with the silicon dioxide substrate, first the unique chemical interaction of ceria with the silicon dioxide substrate softens the surface film of SiO₂ and then the hard alumina particles mechanically abrade the softened film. On the other hand, for Si₃N₄ to be removed at a faster rate, it has to be first oxidized to SiO₂ and only then the synergistic interaction of large and small particles in the modified abrasive can come into play to enhance the RR . At pH values <5, the oxidation of Si₃N₄ to SiO₂ is very slow and hence the modified abrasive always interacts with hard Si₃N₄ surface film during polishing, leading to low Si₃N₄ RR and thus improving selectivity.

Further, since the ceria particles that interact with the polishing material are very soft, the resulting surface smoothness is excellent. This is the advantage of mixed abrasive slurry, where specific interactions between the abrasive and the polishing substrate can be appropriately tailored to control the removal rates of polishing materials to desirable values and simultaneously produce high post-polish surface quality (low surface roughness).

This unique functionality is given only to mixed abrasive slurries and is clearly not demonstrated by single abrasive slurries (data in rows 1-4 in the Example Table).

The following are the reference citations for the numerals 1-4 shown in brackets in the foregoing description:

1. A. Jindal, S. Hegde and S. V. Babu, J. Electrochem. Soc. 150 (5) G314-318 (2003);

2. A. Jindal, S. Hegde and S. V. Babu, Proceedings of the CMP Users Group Meeting, 2001

3. Wei-Heng Shih, David Kisailus and Wan Y. Shih, J. Am. Ceram. Soc., 79 [5], 1155-62 (1996)

4. L. M. Cook, J. Non-Cryst. Solids, 120, 152 (1990)

In summary, the present data describes shallow trench isolation with mixed abrasive slurries containing colloidal ceria and alumina particles. It has been shown that a mixed abrasive slurry of alumina and ceria, without any additives, can yield better shallow trench isolation chemical-mechanical performance than with single abrasive performance.

It is however pointed out that restriction of the experimentals to just two of the inorganic metal oxide abrasives commonly employed in chemical-mechanical polishing, namely a combination of alumina and ceria, was not selected because of any suspicion that none of the other inorganic metal oxides known for use in chemical-mechanical polishing would be operative, nor was the selection arbitrary.

The restriction to just two of the known class, namely alumina and ceria, was elected to follow sensible research practice not to “mix apples with oranges”, so to speak, but to establish proper scientific controls for determining whether mixed abrasive slurries can in fact provide unexpected superior results over single abrasive slurries.

Based upon the above data which has been confirmed, Applicants believe but have not as yet unequivocally confirmed by actual reduction to practice that the invention is not restricted to the combination of silica and ceria, but instead in fact includes mixed abrasive slurries containing at least two inorganic metal oxides, e.g. any of the following per se known in chemical-mechanical polishing, namely at least two or more of the following: alumina, titania, zirconia, germania, silica and ceria.

Confirmation of Applicants belief that the scope of this invention is at least that generic would involve but simple routine experimentation within the expected judgment of the skilled worker in the light of the foregoing detailed description.

In this manner, the following generic claims would inherently include within their scope only those combinations which in fact provide the superior results herein contemplated or, stated another way, if any combination does not do so, then no one would want to employ this combination for any reason taught in this application and there cannot then be any infringement of the appended generic claims. On the other hand, if superior results are provided by any other combination of inorganic metal oxides, then Applicants' presently theoretical opinion as to the scope of the invention has been conclusively vindicated or affirmed as to that combination of oxides and therefore infringement of the claims in point is likewise confirmed.

The undersigned attorney who presented a draft of this application for approval by the named Applicants understands fully the requirements of the patent statute for defining the metes and bounds of what Applicants claim to be their invention and unless the patent code is codified to positively require actual reduction to practice of what is claimed considers that the claims in the case are all formally correct, at least as to scope of the invention, following approval by Applicants.

Since certain changes may be made without departing from the scope of the invention, it is accordingly intended that the foregoing specification in conjunction with the appended drawings shall be interpreted as being illustrative and not in a limiting sense; and the scope of the invention shall be as recited in the appended claims.

What is claimed is:

1. A mixed abrasive slurry for Shallow Trench Isolation Polishing consisting essentially of at least two inorganic metal oxide abrasive material particles at a pH below five in order to control the polish rate selectivity of silicon oxide to silicon nitride and to reduce surface defects,
the inorganic metal oxide abrasive particles consisting of:
(a) particles characterized as being relatively large and hard; and
(b) particles characterized as being relatively small and soft, the relatively small particles in the abrasive slurry being adhered to the surface of the relatively large particles whereby to modify the effective charge of the slurry.

2. A mixed abrasive slurry as defined in claim 1 wherein the relatively large particles possess a mean particle size of from about 80 nm to about 250 nm; and the relatively small particles possess a mean particle size of from about 10 nm to about 40 nm.

3. A mixed abrasive slurry as defined in claim 2 wherein the ratio of relatively large particles to relatively small particles is from about 1:1 to 1:2 by weight.

4. A mixed abrasive slurry as defined in claim 1 wherein the relatively large metal oxide abrasive particles possess a rating of about 7 to about 9 on the mohs hardness scale.

5. A mixed abrasive slurry as defined in claim 4 wherein the relatively small metal oxide abrasive particles possess a rating of about 2 to about 3 on the mohs hardness scale.

6. A mixed abrasive slurry as defined in claim 1 wherein the relatively large abrasive particles are selected from the group consisting of alumina, titania, ceria germania, chromia, iron oxide and zirconia.

7. A mixed abrasive slurry as defined in claim 6 wherein the relatively small abrasive particles are selected from the group consisting of ceria, silica and zirconia.

8. A mixed abrasive slurry as defined in claim 6 wherein the relatively large abrasive particles comprise alumina and the relatively small abrasive particles comprise ceria.

9. A mixed abrasive slurry as defined in claim 1 wherein the polish rate selectivity with the slurry was more than 30 with a surface roughness of less than 1.0

10. A mixed abrasive slurry as defined in claim 6 wherein the pH is on the order of 4.0 or less.

11. A method of preparing integrated circuits consisting of a large plurality of active areas isolated from one another so that the functioning of one active area does not interfere with the neighboring ones, comprising the steps of:
(a) applying a layer of silicon dioxide on one surface of a silicon substrate for the integrated circuit;
(b) applying a layer of silicon nitride over the layer of silicon dioxide;
(c) etching isolated shallow trenches through the applied layer of silicon nitride and into the silicon substrate;
(d) filling the thus formed isolated trenches with silicon dioxide;
(e) removing excess silicon dioxide by the step of chemical-mechanical polishing with an abrasive slurry as defined in claim 1, the chemical-mechanical polishing step being stopped on the isolated silicon nitride layers; and
(f) thereafter removing the silicon nitride.

12. The method as defined in claim 11 wherein the silicon nitride is removed by etching.

13. The method as defined in claim 12 wherein the pH of the slurry is from about 3 to about 4.

14. The method as defined in claim 1 wherein the polish rate selectivity with the mixed abrasive slurry is more than 30 and the surface roughness is less than 1.0 nm.

15. The method as defined in claim 12 wherein the relatively large inorganic metal oxide abrasive materials are selected from the group consisting of alumina, titania, germania, chromia, ceria, iron oxide and zirconia; and the relatively small inorganic metal oxide particles are selected from the group consisting of silica, zirconia and ceria.

16. An integrated circuit prepared by the method as defined in claim 11.
